(19) United States
(12) Patent Application Publication
(10) Pub. No.: US 2015/0046105 A1
(43) Pub. Date: Feb. 12, 2015

(54) VOLTAGE MODE FUEL GAUGE

(71) Applicant: QUALCOMM Incorporated, San Diego, CA (US)

(72) Inventors: Ranjit Kumar Guntreddi, Singapore (SG); Krishnakumar Gopalakrishnan, San Diego, CA (US); Justin T Blackman, Santa Clara, CA (US); Eric I Mikuteit, San Diego, CA (US); Todd R Sutton, Del Mar, CA (US)

(73) Assignee: QUALCOMM Incorporated, San Diego, CA (US)

(21) Appl. No.: 14/253,415

(22) Filed: Apr. 15, 2014

Related U.S. Application Data
(60) Provisional application No. 61/864,241, filed on Aug. 9, 2013.

(51) Int. Cl. G01R 31/36

(52) U.S. Cl. CPC G01R 31/362; G01R 31/3651
USPC 702/63

(57) ABSTRACT

In one embodiment, a circuit comprises a sensor providing a digital signal responsive to a battery voltage on a battery terminal of a battery. The sensor can be an analog-to-digital convertor. A processor is coupled to the sensor and is configured to calculate a state of charge of the battery based on the digital signal at a first time, the digital signal at a second time, and a stored battery profile of open circuit voltage as a function of state of charge at the second time.

### RELATED APPLICATION

This application claims benefit of U.S. provisional application No. 61/864,241, filed Aug. 9, 2013, which is incorporated by reference herein in its entirety.

### BACKGROUND

The disclosure relates to battery fuel gauges, and in particular, to voltage mode fuel gauges.

Unless otherwise indicated herein, the approaches described in this section are not admitted to be prior art by inclusion in this section.

The amount of electric charge that a battery can store is typically referred to as the battery's “capacity”. The state of charge (SoC) of a battery expresses the battery's present capacity as a percentage of the battery's maximum capacity. The SoC of a battery is dependent on inherent chemical characteristics of the battery and characteristics of the electrical system in which the battery is installed, as well as operating conditions of the battery.

Traditionally, battery fuel gauges estimate SoC by combining battery current and voltage information. Simultaneous measurement of battery terminal voltage and current gives the open circuit voltage (OCV), which is used to find the SoC from the OCV/SoC profile of the battery. Current information is integrated over time to compute the amount of charge flow into and out of the battery.

### SUMMARY

The present disclosure describes battery fuel gauge for calculating a state of charge of a battery.

In one embodiment, a circuit comprises a sensor providing a digital signal responsive to a battery voltage on a battery terminal of a battery. A processor is coupled to the sensor and is configured to calculate a state of charge of the battery based on the digital signal at a first time, the digital signal at a second time, and a stored battery profile of open circuit voltage as a function of state of charge at the second time.

In one embodiment, the processor is further configured to determine an average battery terminal voltage over a time period, and to further calculate the state of charge of a battery based on the determined average battery terminal voltage.

In one embodiment, the processor is configured to determine an average battery terminal voltage during a time period by sampling the digital signal and calculating an average voltage from the sampled digital signal.

In one embodiment, the processor is configured to determine a slope of a stored battery profile of open circuit voltage as a function of state of charge at the second time and to further calculate the state of charge of the battery based on the slope.

In one embodiment, the circuit further comprises a memory for storing the battery profile open circuit voltage as a function of state of charge.

In one embodiment, the circuit further comprises a sensor that includes an analog-to-digital converter.

In another embodiment, a circuit comprises an analog-to-digital convertor that provides a first digital signal responsive to an open circuit battery voltage on a battery terminal at an initial detection time and provides a plurality of second digital signals responsive to a plurality of battery voltages on the battery terminal for each of a plurality of detection intervals. A processor is coupled to the analog-to-digital convertor and is configured to calculate a state of charge of a battery based on the first digital signal, the plurality of second digital signals, and a stored battery profile of open circuit voltage as a function of state of charge.

In one embodiment, the processor is further configured to determine, for each detection interval, an average battery terminal voltage for the plurality of second digital signals, and to further calculate, for each detection interval, the state of charge of a battery based on the determined average battery terminal voltage.

In one embodiment, the processor is configured to determine, for each detection interval, an open circuit voltage on the battery terminal voltage, and to further calculate, for each detection interval, an average battery terminal voltage of the detection interval corresponding to a current detection interval and the determined open circuit voltage for an immediately prior detection interval.

In one embodiment, the processor is configured to calculate, for each detection interval, the state of charge of a battery based on the calculated average battery terminal voltage of the detection interval corresponding to a current detection interval and the determined open circuit voltage for an immediately prior detection interval.

In one embodiment, the processor is configured to determine a slope of a stored battery profile of open circuit voltage as a function of state of charge at the last of the second detection times and to further calculate the state of charge of a battery based on the slope.

In one embodiment, the processor is configured to calculate the state of charge of a battery for a detection interval based on the determined state of charge for an immediately prior detection interval and a determined charge drawn from the battery during the current detection interval.

In one embodiment, the circuit further comprises a memory for storing the battery profile of open circuit voltage as a function of state of charge.

In yet another embodiment, a method comprises detecting an initial open circuit battery voltage at a first time; detecting a second open circuit battery voltage at a second time; and calculating a state of charge of a battery based on the initial open circuit battery voltage, the second open circuit battery voltage, and a stored battery profile of open circuit voltage as a function of state of charge.

In one embodiment, the method further comprises determining an average battery terminal voltage during an averaging window, and calculating a state of charge of a battery based on the determined average battery terminal voltage.

In one embodiment, determining an average battery terminal voltage during an averaging window includes sampling the battery voltage and calculating an average voltage from the sampled battery voltage.

In one embodiment, the method further comprises dynamically adjusting a duration of the averaging window based on the slope of the stored battery profile of open circuit voltage as a function of state of charge.

In one embodiment, the method further comprises determining a slope of the stored battery profile of open circuit voltage as a function of state of charge at the second time.

In one embodiment, the method further comprises dynamically adjusting the sampling rate based on the slope of the stored battery profile of open circuit voltage as a function of state of charge.

In one embodiment, the method further comprises determining a first average battery terminal voltage over an interval before the second time to the second time, detecting a third open circuit battery voltage at a third time, and determining a second average battery terminal voltage over from the second time to the third time. Calculating a state of charge of a battery including calculating a first state of charge of the battery based on the determined first average battery terminal voltage, and calculating a second state of charge of the battery based on the determined second average battery terminal voltage and the first state of charge of the battery.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, make apparent to those of skill in the art how embodiments in accordance with the present disclosure may be practiced. In the accompanying drawings:

FIG. 1 is a block diagram illustrating a battery fuel gauge for determining a state of charge of a battery according to an embodiment.

FIG. 2 is a schematic of a battery mode according to an embodiment.

FIG. 3 is a timing diagram illustrating the sampling times of detecting voltage on a battery terminal according to an embodiment.

FIG. 4 shows one battery profile at one temperature of battery voltage as a function of discharging capacity of a battery according to an embodiment.

FIG. 5 is a diagram illustrating an equation for average battery current according to an embodiment according to an embodiment.

FIG. 6 is a diagram illustrating an equation for open circuit voltage of a battery according to an embodiment.

FIG. 7 is a diagram illustrating an equation for state of charge of a battery according to an embodiment.

FIG. 8 is a diagram illustrating an equation for open circuit voltage of a battery according to an embodiment.

FIG. 9 illustrates a simplified diagram illustrating a process flow for determining state of charge of a battery according to an embodiment.

### DETAILED DESCRIPTION

In the following description, for purposes of explanation, numerous examples and specific details are set forth in order to provide a thorough understanding of the present disclosure. It will be evident, however, to one skilled in the art that the present disclosure as expressed in the claims may include some or all of the features in these examples, alone or in combination with other features described below, and may further include modifications and equivalents of the features and concepts described herein.

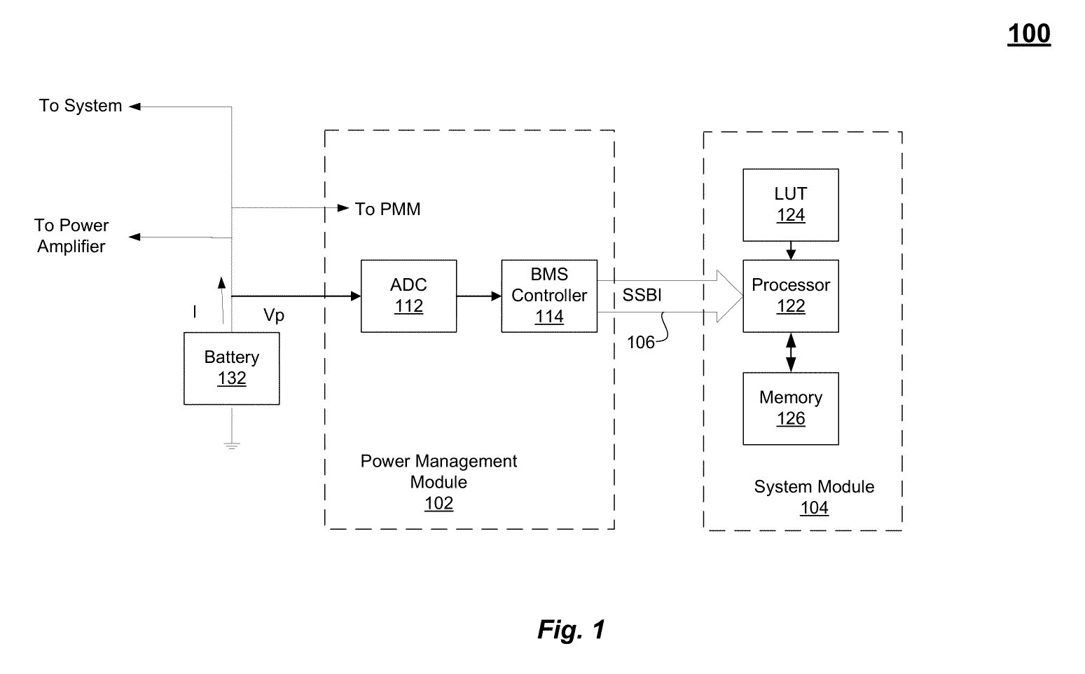

FIG. 1 shows a power management integrated circuit (PMIC) battery fuel gauge 100 according to an embodiment. Battery fuel gauge 100 is a voltage fuel gauge that uses detected battery voltage for determining a state of charge (SoC) of a battery 132. In a typical configuration, battery 132 is connected to power an electronic system (not shown) and power amplifier (not shown), and so a battery current IBAT and a battery voltage VBAT may include effects due to loading on battery 132 by the electronic system and power amplifier. In some embodiments, battery fuel gauge 100 comprises a power management module 102 and a system module 104.

Power management module 102 comprises a voltage analog-to-digital converter (ADC) 112 and a battery management system (BMS) controller 114. ADC 112 is coupled to a battery terminal of battery 132 and operates as a voltage sensor to detect or measure the battery terminal voltage on the battery terminal ADC 112 generates a digital signal based on the detected battery terminal voltage and provides the digital signal to BMS controller 114. As described below, ADC 112 detects the battery terminal voltage at an initial time and at sampled times. In an illustrative example, the sampled times are at a sampling frequency fs. BMS controller 114 processes the digital signal and provides a serial digital signal via a single-wire serial bus interface (SSBI) 106 to system module 104 responsive to the digital signal indicative of the detected battery terminal voltage. The serial digital signal is a serial form of the digital converted detected battery terminal voltages. In some embodiments, SSBI 106 can be another type of communication interface, and BMS controller 114 processes the digital signal from ADC 112 in accordance with the protocol of the communication interface. In some embodiments, BMS controller 114 controls a detection interval as a time period or an averaging window during which the battery terminal voltages are detected, and averaged as described below. In some embodiments, BMS controller 114 controls the sampling frequency fs. BMS controller 114 controls other functions of power management module 102.

System module 104 comprises a processor 122, a look-up table (LUT) 124, and a memory 126. Processor 122 receives the serial digital signal via SSBI 106 from BMS controller 114. As described below, processor 122 calculates an estimation of SoC of battery 132 using the serial digital signal or the detected battery voltages. In some embodiments, processor 122 controls the detection interval. In some embodiments, processor 122 controls the sampling frequency fs.

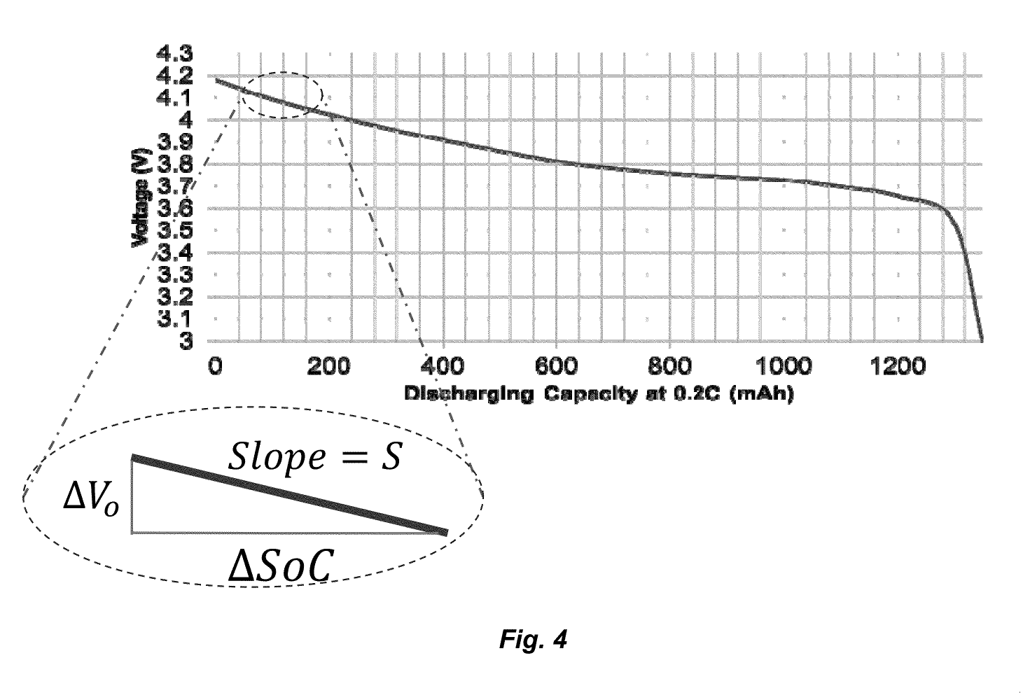

LUT 124 stores battery profile information, such as an open circuit voltage (OCV) as a function of SoC (OCV/SoC) profile of battery 132. The OCV/SoC profile indicates the relationship of the battery voltage as a function of the discharging capacity of a battery. The battery profile information can also include battery series resistance as a function of SoC. The profile stored in LUT 124 can include profiles for a battery over various parameters, such as multiples temperatures. An illustrative example of an OCV/SoC profile is shown in FIG. 4. LUT 124 can be part of memory 126.

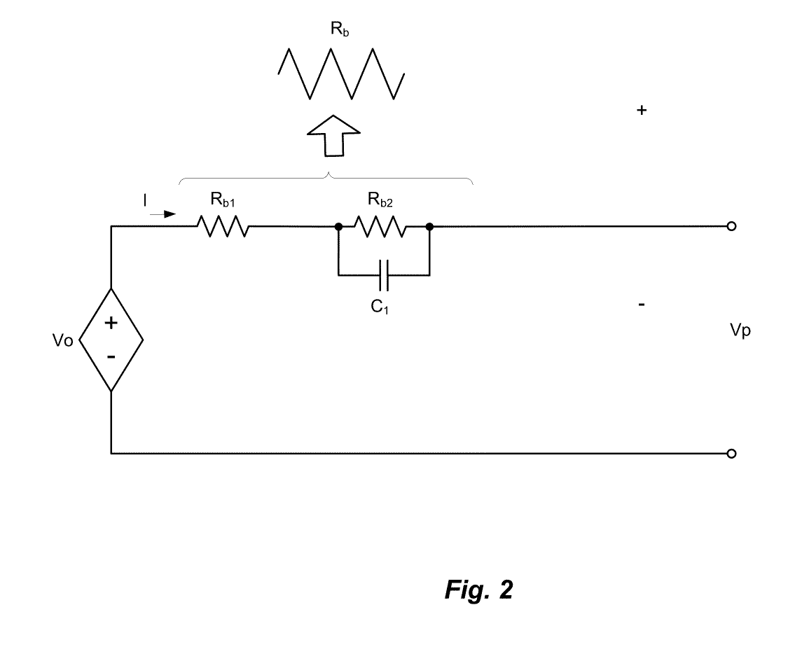

Memory 126 stores instructions for processor 122 to execute an algorithm for estimating the State of charge (SoC) of a battery using only voltage information and without battery current measurement. The instructions include an algorithm that evaluates average battery current based on battery terminal voltage measurements. The algorithm calculates the SoC from the measured battery voltage and the battery profile stored in LUT 124. In some embodiments, the calculation of the SoC is based on a battery model as described in conjunction with FIG. 2. Memory 126 stores results of calculations of processor 122, such as the estimated SoC. Memory 126 can include transitory memory and non-transitory memory.

Although battery fuel gauge 100 is described as including a power management module 102 and system module 104, it is understood that battery fuel gauge 100 can be implemented in other configurations. For example, ADC 112 can provide the digital signal to processor 122 independent of BMS controller 114 or can be part of system module 104.

FIG. 2 is a schematic of a battery model. The battery model may predict the battery voltage of the battery 132, which is output by the battery model as an estimated battery voltage Vp. In some embodiments, the battery profile stored in LUT 124 can be based on an electrical battery model such as shown in FIG. 2. The battery model may include a voltage source to represent an open circuit voltage Vo of the battery. The battery model may include an equivalent series resistance (ESR) Rb1 and a RC parallel network to represent the battery's response to transient load current events. The RC parallel network comprises a resistor Rb2 and a capacitor C1. A battery voltage Vp on the battery terminal can then be computed as the open circuit voltage Vo of the battery minus the voltage drops across the resistor Rb1 and the RC parallel network. Elements of the electrical battery model shown in FIG. 2 are dependent on many factors such as operating temperature of the battery, age of the battery, and so on. The relationships among the battery parameters tend to be nonlinear; e.g., the relationship between the battery OCV and battery SoC is non-linear and temperature dependent. The battery voltage Vp on the battery terminal equals Vo−I*Rb.

In some embodiments, certain simplifying assumptions may be made for the battery model of FIG. 2. For example, the battery can be modelled as a resistor Rb. For example, the resistance Rb equals the resistance Rb1, because the effect of the RC parallel network can be ignored, or the resistance Rb equals the sum of the resistance Rb1 and the resistance Rb2, because the effect of the capacitor C1 can be ignored. As an illustrative example, the battery resistance Rb is used as having no capacitance.

Referring again to FIG. 1, as an illustrative example, ADC 112 detects the battery voltage Vp(k) at a time tk at a sampling frequency fs (or 1/sampling time ts).

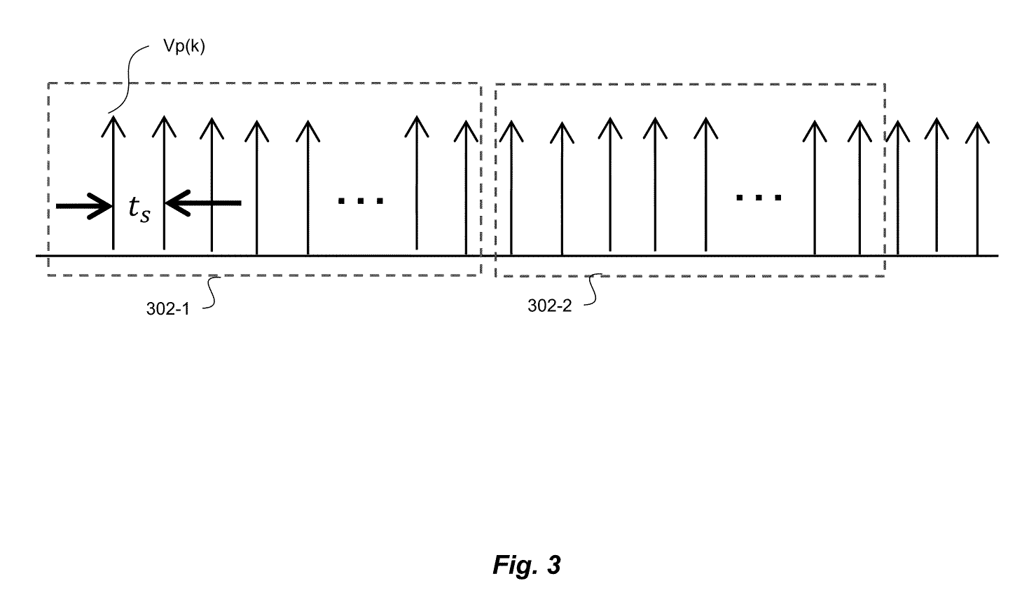

FIG. 3 is a timing diagram illustrating the sampling times of detecting voltage on the battery terminal. Processor 122 averages the detected battery voltage Vp(k) over a detection interval 302 that includes a number n samples. In some embodiments, each detection interval 302-1, 302-2, and so forth has the same number n of samples. In some embodiments, the detection intervals 302 can have different numbers of samples. In some embodiments, the detection intervals 302 can have different durations. For example, the number of samples in a detection interval 302 or the size of the detection intervals 302 can be dynamically adjusted based on the slope of the stored battery profile of open circuit voltage as a function of state of charge. In some embodiments, the sampling frequency fs can be varied. For example, the sampling frequency fs can be dynamically adjusted based on the slope of the stored battery profile of open circuit voltage as a function of state of charge.

Processor 122 calculates the average detected battery voltage Vpavg over the detection interval 302 for the n samples of the detected battery voltage Vp(k) as follows:

$${V}_{{p}_{avg}} = {\sum }_{k = 1}^{n} \frac{{V}_{p} ( k )}{n} . \qquad ( 1 )$$

Using the battery model of FIG. 2, the average open circuit voltage Voavg becomes:

Vₒ_{_{avg}}=Vₚ_{_{avg}}+I_{avg}*R_{b} (2),

where the term “Iavg” is the average battery current from battery 132 calculated for the n samples.

The average open circuit voltage Voavg can be rewritten as:

$${v}_{{o}_{avg}} = \frac{{V}_{0} ( 1 ) + {V}_{0} ( n )}{2} + {v}_{e} ( 1 ) \qquad ( 3 )$$

where the term “Vo(1)” is the initial open circuit voltage, Vo(n) is the open circuit voltage at the sample time n, and the term “Ve(1)” is the initial error voltage. In some embodiments, the error voltage can be from a bandgap voltage source that has not settled or an error in ADC 112. Using the transitive property of equality for equations (2) and (3), and solving for the open circuit voltage Vo(n) results in:

Vₒ(n)=2I_{avg}R_{b}+2Vₚ_{_{avg}}−Vₒ(1)−2vₑ(1) (4)

In some embodiments, the error voltage “Ve(1)” converges to zero, and can be ignored. In some embodiments, the error voltage Ve(1)−Vpavg is much less than Vo(n), and thus is set to zero to simply the equations. In some embodiments, the error voltage is zero, such as if the battery current is constant.

Referring again to FIG. 1, processor 122 uses in the battery profile stored in LUT 124 to determine the average battery current using the slope of the battery profile.

FIG. 4 shows one battery profile at one temperature of the battery voltage as a function of the discharging capacity of a battery. The slope S (change of voltage for the state of charge) at a given time is determined from the stored battery profile. The change in voltage ΔV is related to the change in the state of charge SoC as follows:

$$Δ V = S * Δ SoC = \frac{S * I * Δ t}{FCC} , \qquad ( 5 )$$

where I is the battery current, over a time Δt, and the term “FCC” is the full charge capacity of the battery in the battery profile in LUT 124. The change in voltage ΔV of equation (5) can be rewritten as:

$${V}_{0} ( 1 ) = {V}_{0} ( n ) - \frac{{I}_{avg} {nt}_{s}}{FCC} S . \qquad ( 6 )$$

Solving for the voltage at the time n, equation (6) can be rewritten as:

$${V}_{0} ( n ) = {V}_{0} ( 1 ) - \frac{{I}_{avg} {nt}_{s}}{FCC} S . \qquad ( 7 )$$

The average current Iavg can be determined using equations (4) and (7) as follows:

$${I}_{avg} = \frac{2 ( {V}_{o} ( 1 ) + {v}_{e} ( 1 ) - {V}_{{p}_{avg}} )}{2 {R}_{b} + \frac{{nt}_{S} S}{FCC}} . \qquad ( 8 )$$

The voltage Vo(n) at time n is

$${V}_{0} ( n ) = {V}_{0} ( 1 ) - \frac{\frac{2 {nt}_{S} S}{FCC} ( {V}_{o} ( 1 ) + {v}_{e} ( 1 ) - {V}_{{p}_{avg}} )}{2 {R}_{b} + \frac{{nt}_{S} S}{FCC}} . \qquad ( 9 )$$

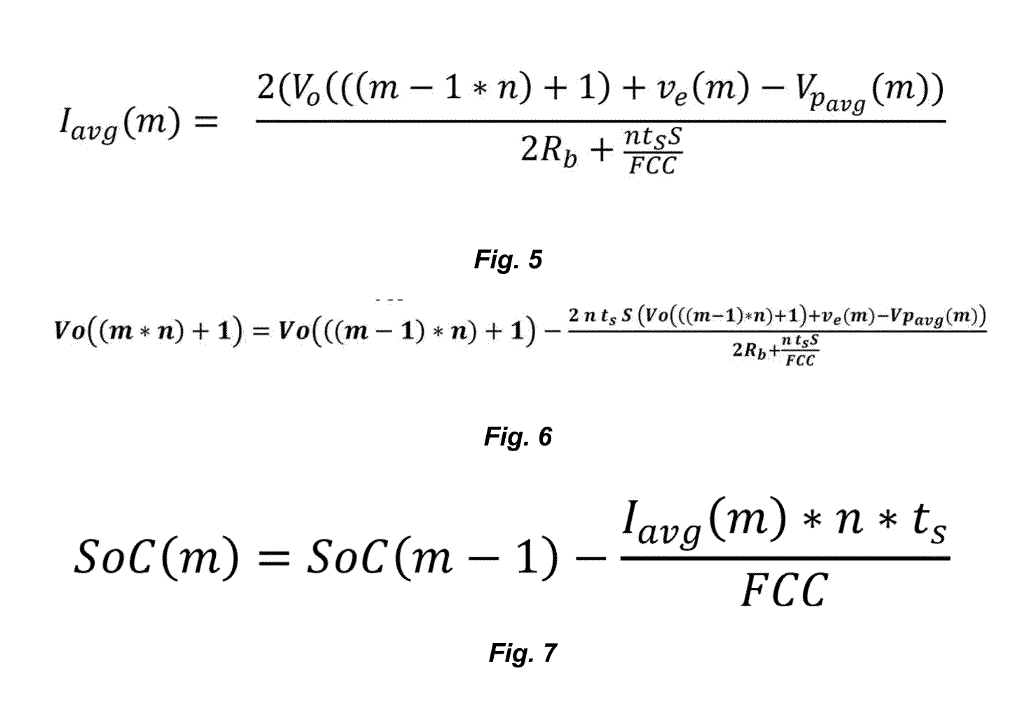

Referring again to FIG. 3, processor 122 estimates the state of charge of battery 132 by averaging n samples from ADC 112 for each detection interval 302. Each detection interval 302 can be considered an m^{th} evaluation of SoC. At the m^{th} evaluation, the output data from ADC 112 from time t=(m−1)*n*ts to time t=m*n*ts is averaged by processor 122. Specifically the output data is averaged using the equations shown in FIGS. 5-7.

FIG. 5 is a diagram illustrating an equation for the average battery current Iavg(m) at the m^{th} evaluation by processor 122. The equation of FIG. 5 is analogous to equation (8) above at the m^{th} evaluation.

FIG. 6 is a diagram illustrating an equation for the voltage Vo((m*n)+1) at the m^{th} evaluation by processor 122. The equation of FIG. 6 is analogous to equation (9) above at the m^{th} evaluation for m*n samples.

FIG. 7 is a diagram illustrating an equation for the state of charge SoC(m) at the m^{th} evaluation by processor 122. The state of charge SoC(m) is based on the state of charge SoC(m−1) at the previous (m−1)^{th} evaluation less the normalized charge (e.g., normalized to FCC) during last detection interval 302 (namely, the last n samples times the sample time ts). In some embodiments, the state of charge SoC(m) can be calculated from Vo((m*n)+1) using the OCV/SoC profile in LUT 124.

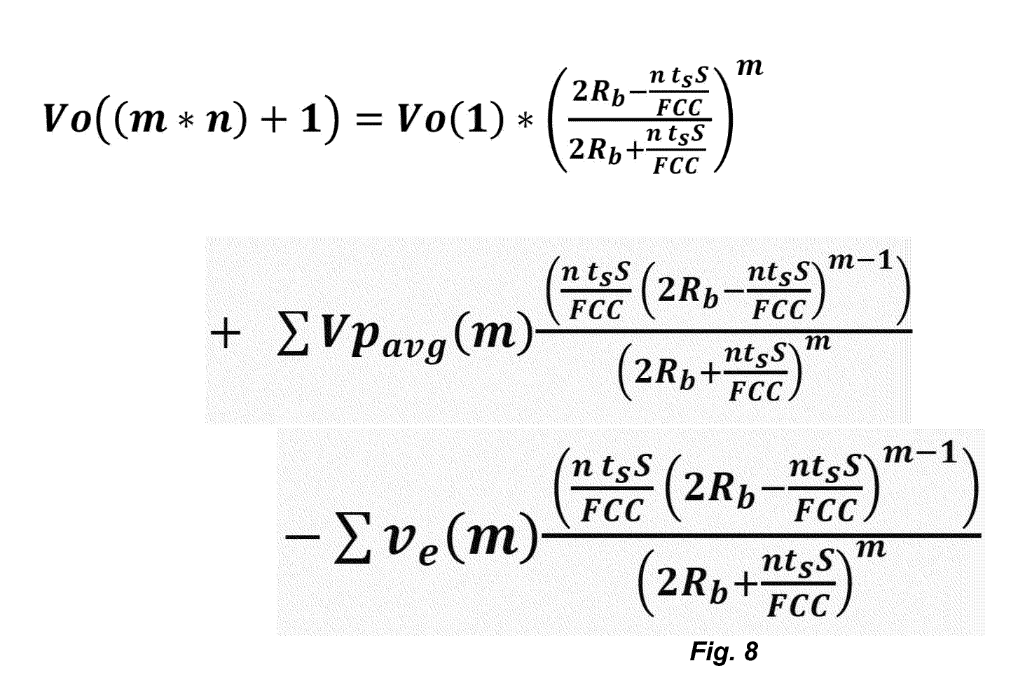

FIG. 8 is a diagram illustrating an equation for the voltage Vo((m*n)+1) at the m^{th} evaluation by processor 122. The equation of FIG. 8 is an alternative form to the equation of FIG. 6. Vo((M*N)+1) is a weighted sum of the initial open circuit voltage Vo(1) and all average voltage Vpavg measurements and error voltages Ve until the time t=m*n*ts. Each weight gradually converges towards zero. Thus, the SoC evaluated at any point has less dependency on earlier voltage measurements and errors. Accordingly, this methods has some ability to self-correct its measurement errors.

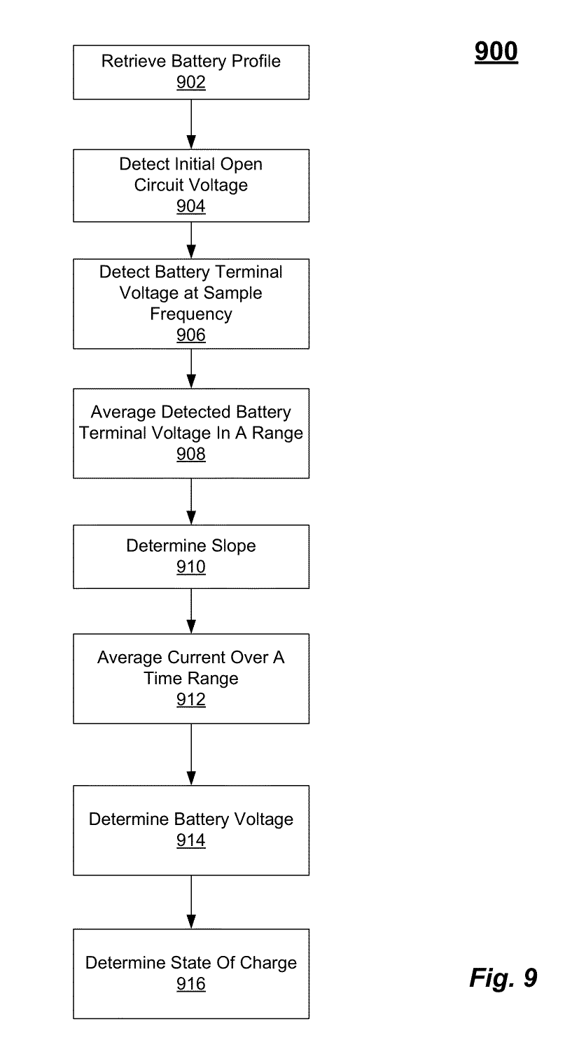

FIG. 9 illustrates a simplified diagram illustrating a process flow 900 for determining state of charge of a battery according to an embodiment. At 902, processor 122 retrieves the battery profile for the OCV/SoC from LUT 124, such as after power on. At 904, ADC 112 detects the initial open circuit voltage Vo(1) of battery 132. At 906, ADC 112 detects battery terminal voltage Vo(k) for each time k at the sample frequency fs. At 908, processor 122 averages the battery terminal voltage Vo(k) in a detection interval 302 or every predetermined number (e.g., n) of samples. At 910, processor 122 determines a slope of the OCV/SoC profile at a time m. At 912, processor 122 calculates an average current over a time range (e.g., from sample 1 to m), using, for example, the equation of FIG. 5. At 914, processor 122 determines a battery voltage at a time m, using, for example, the equation of FIG. 6. At 916, processor 122 determines a state of charge of battery 132 at a time m, using, for example, the equation of FIG. 7.

Because ADC 102 measures battery terminal voltage and does not measure current, battery fuel gauge 100 does not need sensing resistors, sensing field-effect transistors (FETs) or a current ADC.

Battery fuel gauge 100 can be used with various battery chemistries and battery profiles. Battery fuel gauge 100 can be used without feedback from software of the external system. Battery fuel gauge 100 can be used in systems where an estimate of battery current drawn by the system is desired.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations and equivalents may be employed without departing from the scope of the present disclosure as defined by the claims.

What is claimed is:

1. A circuit comprising:
a sensor providing a digital signal responsive to a battery voltage on a battery terminal of a battery; and
a processor coupled to the sensor and configured to calculate a state of charge of the battery based on the digital signal at a first time, the digital signal at a second time, and a stored battery profile of open circuit voltage as a function of state of charge at the second time.

2. The circuit of claim 1 wherein the processor is further configured to determine an average battery terminal voltage over a time period, and to further calculate the state of charge of a battery based on the determined average battery terminal voltage.

3. The circuit of claim 2 wherein the processor is configured to determine an average battery terminal voltage during a time period by sampling the digital signal and calculating an average voltage from the sampled digital signal.

4. The circuit of claim 1 wherein the processor is configured to determine a slope of a stored battery profile of open circuit voltage as a function of state of charge at the second time and to further calculate the state of charge of the battery based on the slope.

5. The circuit of claim 1 further comprising a memory for storing the stored battery profile open circuit voltage as a function of state of charge.

6. The circuit of claim 1 wherein the sensor is an analog-to-digital converter.

7. A circuit comprising:
an analog-to-digital convertor providing a first digital signal responsive to an open circuit battery voltage on a battery terminal at an initial detection time and providing a plurality of second digital signals responsive to a plurality of battery voltages on the battery terminal for each of a plurality of detection intervals; and
a processor coupled to the analog-to-digital convertor and configured to calculate a state of charge of a battery based on the first digital signal, the plurality of second digital signals, and a stored battery profile of open circuit voltage as a function of state of charge.

8. The circuit of claim 7 wherein the processor is further configured to determine, for each detection interval, an average battery terminal voltage for the plurality of second digital signals, and to further calculate, for each detection interval, the state of charge of a battery based on the determined average battery terminal voltage.

9. The circuit of claim 8 wherein the processor is configured to determine, for each detection interval, an open circuit voltage on the battery terminal voltage, and to further calculate, for each detection interval, an average battery terminal voltage of the detection interval corresponding to a current detection interval and the determined open circuit voltage for an immediately prior detection interval.

10. The circuit of claim 9 wherein the processor is configured to calculate, for each detection interval, the state of charge of a battery based on the calculated average battery terminal voltage of the detection interval corresponding to a current detection interval and the determined open circuit voltage for an immediately prior detection interval.

11. The circuit of claim 7 wherein the processor is configured to determine a slope of a stored battery profile of open circuit voltage as a function of state of charge at the last of the second detection times and to further calculate the state of charge of a battery based on the slope.

12. The circuit of claim 7 wherein the processor is configured to calculate the state of charge of a battery for a detection interval based on the determined state of charge for an immediately prior detection interval and a determined charge drawn from the battery during the current detection interval.

13. The circuit of claim 7 further comprising a memory for storing the stored battery profile of open circuit voltage as a function of state of charge.

14. A method comprising:
detecting an initial open circuit battery voltage at a first time;
detecting a second open circuit battery voltage at a second time; and
calculating a state of charge of a battery based on the initial open circuit battery voltage, the second open circuit battery voltage, and a stored battery profile of open circuit voltage as a function of state of charge.

15. The method of claim 14 further comprising
determining an average battery terminal voltage during an averaging window,
wherein calculating a state of charge of a battery including calculating a state of charge of a battery based on the determined average battery terminal voltage.

16. The method of claim 15 wherein determining an average battery terminal voltage during an averaging window includes sampling the battery voltage and calculating an average voltage from the sampled battery voltage.

17. The method of claim 15 further comprising dynamically adjusting a duration of the averaging window based on the slope of the stored battery profile of open circuit voltage as a function of state of charge.

18. The method of claim 14 further comprising determining a slope of the stored battery profile of open circuit voltage as a function of state of charge at the second time.

19. The method of claim 14 further comprising dynamically adjusting the sampling rate based on the slope of the stored battery profile of open circuit voltage as a function of state of charge.

20. The method of claim 14 further comprising
determining a first average battery terminal voltage over an interval before the second time to the second time,
wherein calculating a state of charge of a battery including calculating a first state of charge of the battery based on the determined first average battery terminal voltage,
the method further comprising:
detecting a third open circuit battery voltage at a third time; and
determining a second average battery terminal voltage over from the second time to the third time,
wherein calculating a state of charge of a battery including calculating a second state of charge of the battery based on the determined second average battery terminal voltage and the first state of charge of the battery.
